(19) United States
(12) Patent Application Publication
(10) Pub. No.: US 2025/0192025 A1
(43) Pub. Date: Jun. 12, 2025

(54) SEMICONDUCTOR DEVICE AND METHOD OF MANUFACTURING THE SAME

(71) Applicant: Renesas Electronics Corporation, Tokyo (JP)

(72) Inventors: Yuki SUGIYAMA, Tokyo (JP); Eiji HIRAIWA, Tokyo (JP)

(21) Appl. No.: 18/915,709

(22) Filed: Oct. 15, 2024

(30) Foreign Application Priority Data
Dec. 11, 2023 (JP) 2023-208796

(51) Int. Cl. H01L 23/522; H01L 21/768

(52) U.S. Cl. CPC H01L 23/5223; H01L 21/76819; H01L 21/76877; H01L 21/76892; H01L 23/5226; H01L 23/5228

(57) ABSTRACT

A lower electrode is formed in a first wiring layer. In a second wiring layer located over the first wiring layer, two wirings having a thickness greater than that of the lower electrode are formed. Between the first wiring layer and the second wiring layer, a dielectric film and an upper electrode are formed over the lower electrode. A resistor element is formed over the two wirings. The lower electrode, the dielectric film, and the upper electrode function as a capacitor element.

### CROSS-REFERENCE TO RELATED APPLICATIONS

The disclosure of Japanese Patent Application No. 2023-208796 filed on Dec. 11, 2023, including the specification, drawings and abstract is incorporated herein by reference in its entirety.

### BACKGROUND

The present invention relates to a semiconductor device and a method of manufacturing the same, particularly to a semiconductor device including a capacitor element and a resistor element formed in a multilayer wiring layer, and a method of manufacturing the same.

In recent semiconductor devices, the number of wiring layers has been increasing. By providing capacitor elements and resistor elements between wiring layers, it is possible to suppress the increase in the planar size of the semiconductor device and promote the miniaturization of the semiconductor device.

There are disclosed techniques listed below.
[Patent Document 1] Japanese Unexamined Patent Application Publication No. 2005-191182
[Patent Document 2] Japanese Unexamined Patent Application Publication No. 2023-58091

Patent Document 1 discloses a capacitor element having a lower electrode, a capacitor dielectric film, and an upper electrode sequentially laminated thereon. This lower electrode is formed in the wiring layer and is formed by the same manufacturing step used for forming the wiring.

Patent Document 2 discloses a technique for forming a resistor element made of materials such as silicon chromium (SiCr) between the lower wiring layer and the upper wiring layer.

### SUMMARY

As in Patent Document 1, a capacitor element, for example, is used in high-precision analog circuits that require high relative accuracy. When using the wiring in the same wiring layer as the lower electrode of the capacitor element, the relative accuracy changes depending on the configuration of that wiring, and the characteristics of the capacitor element vary. Therefore, there are restrictions on the wiring that can be used for the lower electrode. Relative accuracy refers to the magnitude of variation in characteristics among a plurality of elements formed in the same semiconductor substrate. Good relative accuracy means that the variation in characteristics among a plurality of elements is small enough to meet the requirements of high-precision analog circuits.

Furthermore, as a resistor element like in Patent Document 2, a conductive film having a thickness of about 10 nm is used. This resistor element is formed between the upper wiring layer and the lower wiring layer. During the patterning of the upper wiring formed in the upper wiring layer, over-etching is performed, but the thicker the upper wiring, the longer the over-etching time becomes. Therefore, if the thickness of the upper wiring is large and the thickness of the interlayer dielectric film formed on the resistor element is small, there is a risk that the over-etching will reach the resistor element.

In that case, there is a risk that the thickness of the resistor element decreases, or part of the resistor element disappears, causing the characteristics of the resistor element to vary. Therefore, there are restrictions on the placement of the resistor element. Especially, the shorter the distance between a plurality of wiring layers, the more likely the above problem occurs.

Therefore, when capacitor elements and resistor elements are provided between wiring layers, a technique that improves the relative accuracy of the capacitor elements and maintains the characteristics of the resistor elements, thereby enhancing the performance of the semiconductor device and securing the reliability of the semiconductor device, is desired.

Other objectives and novel features will become apparent from the description of this specification and the accompanying drawings.

The typical ones of the embodiments disclosed in the present application will be briefly described as follows.

In one embodiment, a semiconductor device includes a first wiring formed in a first wiring layer, a second wiring and a third wiring each formed in a second wiring layer located over the first wiring layer and having a thickness greater than that of the first wiring, a first dielectric film and a first conductive film formed between the first wiring layer and the second wiring layer and over the first wiring, and a second conductive film formed over the second wiring and the third wiring. The first wiring, the first dielectric film, and the first conductive film function as a capacitor element, and the second conductive film functions as a first resistor element electrically connected to the second wiring and the third wiring.

In one embodiment, a manufacturing method of the semiconductor device includes a step of forming a first interlayer dielectric film over the semiconductor substrate, a step of forming a first wiring and a first dielectric film and a first conductive film sequentially laminated over the first wiring over the first interlayer dielectric film, a step of forming a second interlayer dielectric film covering the first wiring, the first dielectric film, and the first conductive film, a step of forming a second wiring and a third wiring over the second interlayer dielectric film, a step of forming a third interlayer dielectric film covering the second wiring and the third wiring, and a step of forming a second conductive film over the third interlayer dielectric film. The thickness of the first wiring is smaller than the thickness of each of the second wiring and the third wiring, and the first wiring, the first dielectric film, and the first conductive film function as a capacitor element, and the second conductive film functions as a first resistor element electrically connected to the second wiring and the third wiring.

According to one embodiment, it is possible to improve the performance of a semiconductor device and secure the reliability of the semiconductor device.

### BRIEF DESCRIPTION OF THE DRAWINGS

FIG. 1 is a cross-sectional view showing a semiconductor device according to a first embodiment.

FIG. 2 is a main portion cross-sectional view showing the semiconductor device according to the first embodiment.

FIG. 3 is a main portion cross-sectional view showing the parameters of each component in FIG. 2.

FIG. 4 is a cross-sectional view showing a manufacturing step of the semiconductor device according to the first embodiment.

FIG. 5 is a cross-sectional view showing a manufacturing step following FIG. 4.

FIG. 6 is a cross-sectional view showing a manufacturing step following FIG. 5.

FIG. 7 is a main portion cross-sectional view showing a manufacturing step following FIG. 6.

FIG. 8 is a main portion cross-sectional view showing a manufacturing step following FIG. 7.

FIG. 9 is a main portion cross-sectional view showing a manufacturing step following FIG. 8.

FIG. 10 is a main portion cross-sectional view showing a manufacturing step following FIG. 9.

FIG. 11 is a main portion cross-sectional view showing a manufacturing step following FIG. 10.

FIG. 12 is a main portion cross-sectional view showing a manufacturing step following FIG. 11.

FIG. 13 is a main portion cross-sectional view showing a manufacturing step following FIG. 12.

FIG. 14 is a main portion cross-sectional view showing a manufacturing step following FIG. 13.

FIG. 15 is a main portion cross-sectional view for explaining issues during the manufacturing step.

FIG. 16 is a main portion cross-sectional view for explaining issues during the manufacturing step.

FIG. 17 is data for explaining the relative accuracy of the capacitor element and the resistor element.

FIG. 18 is a main portion cross-sectional view showing a semiconductor device according to a second embodiment.

FIG. 19 is a cross-sectional view showing a semiconductor device according to a third embodiment.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. Furthermore, in the following embodiments, descriptions of the same or similar parts will not be repeated in principle except when particularly necessary.

Moreover, in this application, the X direction, Y direction, and Z direction are described as intersecting each other and being orthogonal to each other. The Z direction is orthogonal to an upper surface of a semiconductor substrate SUB. In this application, the Z direction is described as the vertical direction, height direction, or thickness direction of a certain structure.

### First Embodiment

### Structure of Semiconductor Device

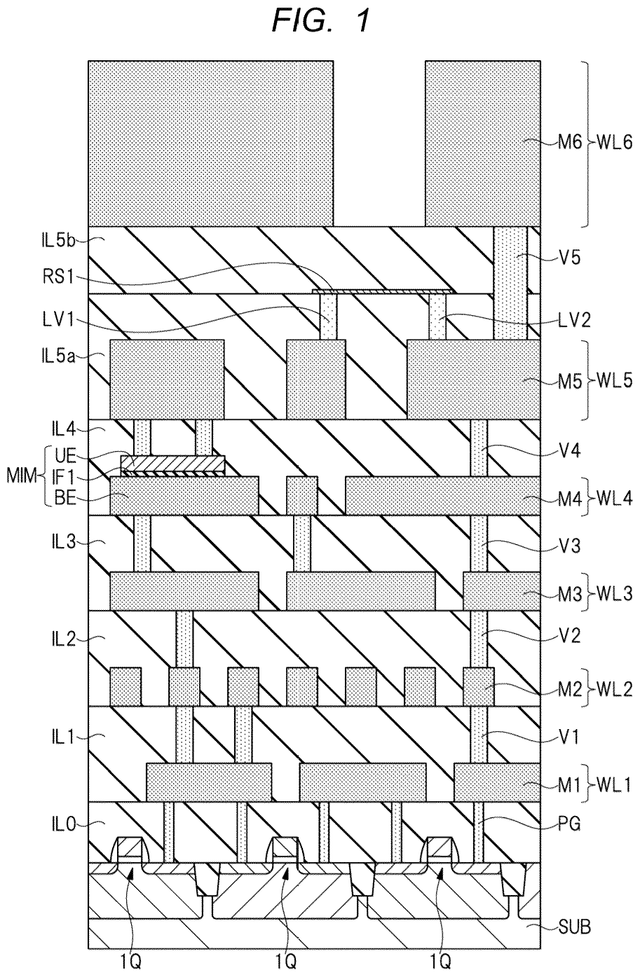

As shown in FIG. 1, the semiconductor device includes the semiconductor substrate SUB, a plurality of transistors 1Q, a multilayer wiring layer formed over the semiconductor substrate SUB, and a capacitor element MIM and a resistor element RS1 formed between wiring layers.

The multilayer wiring layer has a plurality of wiring layers. In the first embodiment, the plurality of wiring layers includes a wiring layer WL1, a wiring layer WL2, a wiring layer WL3, a wiring layer WL4, a wiring layer WL5, and a wiring layer WL6. The wiring layer WL6 is the uppermost wiring layer of the multilayer wiring layer. The wiring layer WL1 includes a plurality of wirings M1. The wiring layer WL2 includes a plurality of wirings M2. The wiring layer WL3 includes a plurality of wirings M3. The wiring layer WL4 includes a plurality of wirings M4. The wiring layer WL5 includes a plurality of wirings M5. The wiring layer WL6 includes a plurality of wirings M6.

The semiconductor substrate SUB is made of, for example, p-type single-crystal silicon. In the semiconductor substrate SUB, a plurality of element isolation portions are formed that define areas where a plurality of semiconductor elements are formed. Also, in the semiconductor substrate SUB, well regions with p-type or n-type impurities introduced are formed. In the well regions, source regions and drain regions with p-type or n-type impurities introduced are formed. Over the well regions, gate electrodes are formed through gate dielectric films. In FIG. 1, as a semiconductor element, the transistor 1Q, which is a MOSFET (Metal Oxide Semiconductor Field Effect Transistor), is formed. The transistor 1Q includes a gate dielectric film, a gate electrode, a source region, and a drain region.

Over the semiconductor substrate SUB, interlayer dielectric film IL0 is formed so as to cover the plurality of transistors 1Q. The interlayer dielectric film IL0 includes, for example, a silicon oxide film. In the interlayer dielectric film IL0, a plurality of plugs PG are formed so as to be connected to the semiconductor substrate SUB. Each of the plurality of plugs PG is buried in holes formed in the interlayer dielectric film IL0 and includes a laminated film containing, for example, a titanium nitride film and a tungsten film. Over the interlayer dielectric film IL0, the plurality of wirings M1 are formed so as to be connected to the plurality of plugs PG.

An interlayer dielectric film IL1 is formed over the interlayer dielectric film IL0 so as to cover the plurality of wirings M1. The interlayer dielectric film IL1 includes, for example, a silicon oxide film. A plurality of vias V1 are formed in the interlayer dielectric film IL1 so as to be connected to the plurality of wirings M1. The plurality of vias V1 are buried in holes formed in the interlayer dielectric film IL1 and include a laminated film containing, for example, a titanium nitride film and a tungsten film. The plurality of wirings M2 are formed over the interlayer dielectric film IL1 so as to be connected to the plurality of vias V1.

An interlayer dielectric film IL2 is formed over the interlayer dielectric film IL1 so as to cover the plurality of wirings M2. The interlayer dielectric film IL2 includes, for example, a silicon oxide film. In the interlayer dielectric film IL2, a plurality of vias V2 are formed so as to be connected to the plurality of wirings M2. The plurality of vias V2 are buried in holes formed in the interlayer dielectric film IL2 and include a laminated film containing, for example, a titanium nitride film and a tungsten film. Over the interlayer dielectric film IL2, the plurality of wirings M3 are formed so as to be connected to the plurality of vias V2.

An interlayer dielectric film IL3 is formed over the interlayer dielectric film IL2 so as to cover the plurality of wirings M3. The interlayer dielectric film IL3 includes, for example, a silicon oxide film. In the interlayer dielectric film IL3, a plurality of vias V3 are formed so as to be connected to the plurality of wirings M3. The plurality of vias V3 are buried in holes formed in the interlayer dielectric film IL3 and include a laminated film containing, for example, a titanium nitride film and a tungsten film. Over the interlayer dielectric film IL3, the plurality of wirings M4 are formed so as to be connected to the plurality of vias V3.

The plurality of wirings M4 have a lower electrode BE of the capacitor element MIM. A dielectric film IF1 is formed over the lower electrode BE. The dielectric film IF1 is, for example, a silicon oxide film, a silicon oxynitride film, or a silicon nitride film, or a laminated film appropriately laminating these films. An upper electrode UE is formed over the dielectric film IF1. The upper electrode UE is a conductive film, including, for example, a titanium nitride film. The dielectric film IF1 and the upper electrode UE are formed between the wiring layer WL4 and the wiring layer WL5. The lower electrode BE, the dielectric film IF1, and the upper electrode UE function as the capacitor element MIM.

An interlayer dielectric film IL4 is formed over the interlayer dielectric film IL3 so as to cover the plurality of wirings M4 and the capacitor element MIM. The interlayer dielectric film IL4 includes, for example, a silicon oxide film. In the interlayer dielectric film IL4, a plurality of vias V4 are formed so as to be connected to the plurality of wirings M4. Also, in the interlayer dielectric film IL4, the plurality of vias V4 connected to the upper electrode UE of the capacitor element MIM are also formed. The plurality of vias V4 are buried in holes formed in the interlayer dielectric film IL4 and include a laminated film containing, for example, a titanium nitride film and a tungsten film. Over the interlayer dielectric film IL4, the plurality of wirings M5 are formed so as to be connected to the plurality of vias V4.

An interlayer dielectric film IL5a is formed over the interlayer dielectric film IL4 so as to cover the plurality of wirings M5. The interlayer dielectric film IL5a includes, for example, a silicon oxide film. In the interlayer dielectric film IL5a, a local via LV1 and a local via LV2 are formed so as to be connected to different wirings M5, respectively. The local via LV1 and the local via LV2 are buried in holes formed in the interlayer dielectric film IL5a and include a laminated film containing, for example, a titanium nitride film and a tungsten film.

Over the interlayer dielectric film IL5a, the resistor element RS1 is formed so as to be connected to the local via LV1 and the local via LV2. That is, the resistor element RS1 is electrically connected to two different wirings M5 via the local via LV1 and the local via LV2. The resistor element RS1 is a conductive film. The resistor element RS1 includes at least one of a silicon chromium film (SiCr film), a silicon chromium film with carbon introduced (SiCrC film), a nickel chromium film (NiCr film), a titanium nitride film (TiN film), and a tantalum nitride film (TaN film).

An interlayer dielectric film IL5b is formed over the interlayer dielectric film IL5a so as to cover the resistor element RS1. The interlayer dielectric film IL5b includes, for example, a silicon oxide film. A plurality of vias V5 are formed in the interlayer dielectric film IL5b and the interlayer dielectric film IL5a so as to be connected to the plurality of wirings M5. The plurality of vias V5 are buried in holes formed in the interlayer dielectric film IL5b and the interlayer dielectric film IL5a and include a laminated film containing, for example, a titanium nitride film and a tungsten film. The plurality of wirings M6 are formed over the interlayer dielectric film IL5b so as to be connected to the plurality of vias V5.

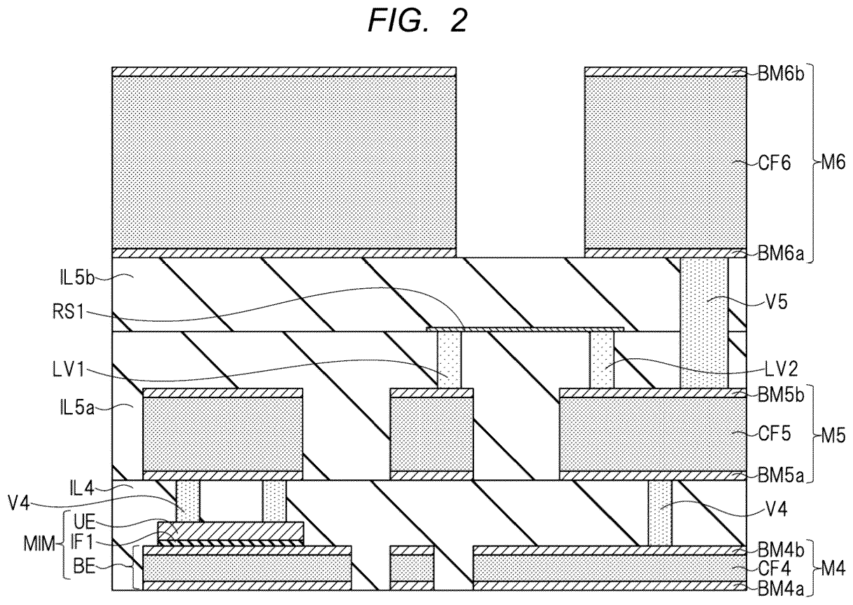

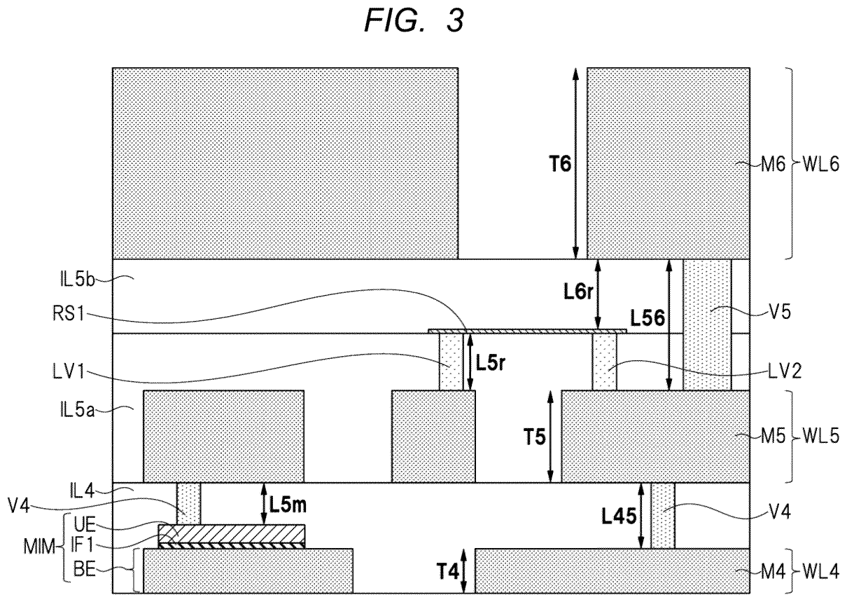

FIG. 2 is an enlarged cross-sectional view of a portion where the capacitor element MIM and the resistor element RS1 are formed in FIG. 1. FIG. 3 is a cross-sectional view showing the same portion as FIG. 2. In FIG. 3, some components and some hatchings are omitted to facilitate the explanation of the thickness of each wiring, among other features.

As shown in FIG. 2, the wiring M4 includes a lower barrier metal film BM4a, a conductive film CF4 formed over the lower barrier metal film BM4a, and an upper barrier metal film BM4b formed over the conductive film CF4. The wiring M5 includes a lower barrier metal film BM5a, a conductive film CF5 formed over the lower barrier metal film BM5a, and an upper barrier metal film BM5b formed over the conductive film CF5. The wiring M6 includes a lower barrier metal film BM6a, a conductive film CF6 formed over the lower barrier metal film BM6a, and an upper barrier metal film BM6b formed over the conductive film CF6.

The configurations of the wiring M1, the wiring M2, and the wiring M3 are similar to that of the wiring M4. That is, the wiring M1, the wiring M2, and the wiring M3 each have a barrier metal film similar to the lower barrier metal film BM4a, a conductive film similar to the conductive film CF4, and a barrier metal film similar to the upper barrier metal film BM4b.

The lower barrier metal film BM4a, the lower barrier metal film BM5a, and the lower barrier metal film BM6a each include a titanium film and a titanium nitride film formed over the titanium film. The conductive film CF4, the conductive film CF5, and the conductive film CF6 each include an aluminum film or an aluminum alloy film to which copper or silicon has been added. The upper barrier metal film BM4b, the upper barrier metal film BM5b, and the upper barrier metal film BM6b each include a titanium nitride film.

The thickness T5 of the wiring M5 is greater than the thickness T4 of the wiring M4. The thickness T6 of the wiring M6 is greater than the thickness T5 of the wiring M5. The wiring layer WL6 is often used for routing power. To suppress voltage drop, the thickness T6 of the wiring M6 is set to be greater than the thickness of other wirings such as wiring M4.

The thickness T4 of the wiring M4 is, for example, 220 nm or more and 360 nm or less. The thickness of the upper barrier metal film BM4b is, for example, 50 nm or more and 70 nm or less. The thickness of the conductive film CF4 is, for example, 130 nm or more and 230 nm or less. The thickness of the lower barrier metal film BM4a is, for example, 40 nm or more and 60 nm or less.

The thickness T5 of the wiring M5 is, for example, 550 nm or more and 690 nm or less. The thickness of the upper barrier metal film BM5b is, for example, 60 nm or more and 80 nm or less. The thickness of the conductive film CF5 is, for example, 450 nm or more and 550 nm or less. The thickness of the lower barrier metal film BM5a is, for example, 40 nm or more and 60 nm or less.

The thickness T6 of the wiring M6 is, for example, 1000 nm or more and 1640 nm or less. The thickness of the upper barrier metal film BM6b is, for example, 60 nm or more and 80 nm or less. The thickness of the conductive film CF6 is, for example, 900 nm or more and 1500 nm or less. The thickness of the lower barrier metal film BM6a is, for example, 40 nm or more and 60 nm or less.

The thickness of the dielectric film IF1 is, for example, 20 nm or more and 50 nm or less. The thickness of the upper electrode UE is, for example, 50 nm or more and 150 nm or less. The thickness of the resistor element RS1 is, for example, 5 nm or more and 20 nm or less.

The distance L56 between the wiring layer WL5 and the wiring layer WL6 is longer than the distance L45 between the wiring layer WL4 and the wiring layer WL5. The distances between the wiring layer WL1 and the wiring layer WL2, between the wiring layer WL2 and the wiring layer WL3, and between the wiring layer WL3 and the wiring layer WL4 are the same as the distance L45.

The distance L45 is, for example, 250 nm or more and 350 nm or less. The distance L45 corresponds to the thickness of the part of the interlayer dielectric film IL4 located over the wiring M4 and corresponds to the height of the via V4 that electrically connects the wiring M4 and the wiring M5.

The distance L56 is, for example, 500 nm or more and 650 nm or less. The distance L56 corresponds to a sum of the thickness of the part of the interlayer dielectric film IL5a located over the wiring M5 and the thickness of the part of the interlayer dielectric film IL5b located over the wiring M5 and corresponds to the height of the via V5 that electrically connects the wiring M5 and the wiring M6.

The distance between the upper electrode UE and the wiring layer WL5 (wiring M5) L5m is, for example, 50 nm or more and 280 nm or less. The distance L5m corresponds to the thickness of the part of the interlayer dielectric film IL4 located over the upper electrode UE and corresponds to the height of the via V4 that electrically connects the upper electrode UE and the wiring M5.

The distance between the resistor element RS1 and the wiring layer WL5 (wiring M5) L5r is, for example, 200 nm or more and 230 nm or less. The distance L5r corresponds to the thickness of the part of the interlayer dielectric film IL5a located over the wiring M4 and corresponds to the height of the local via LV1 and the height of the local via LV2 that electrically connect the resistor element RS1 and the wiring M5.

The distance between the resistor element RS1 and the wiring layer WL6 (wiring M6) L6r is, for example, 250 nm or more and 445 nm or less. The distance L6r corresponds to the thickness of the part of the interlayer dielectric film IL5b located over the resistor element RS1.

It should be noted that the distance L45, the distance L56, the distance L5m, the distance L5r, and the distance L6r are distances in the direction orthogonal (Z direction) to the upper surface of the semiconductor substrate SUB.

### Manufacturing Method of Semiconductor Device

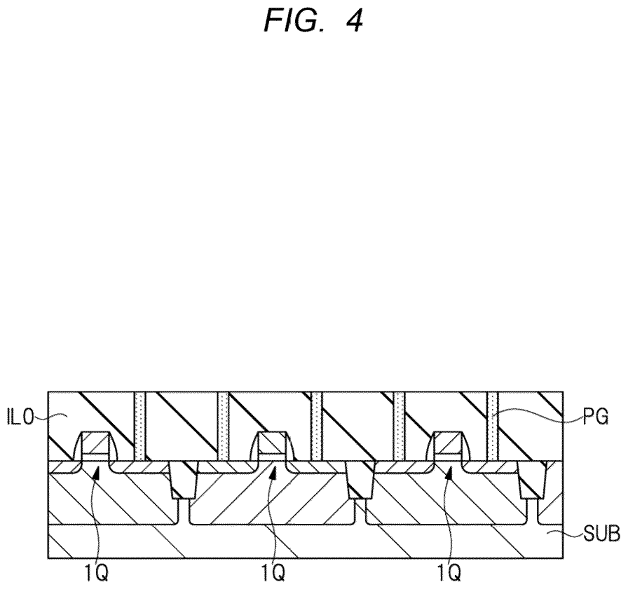

As shown in FIG. 4, first, the semiconductor substrate SUB is prepared. Next, a plurality of element isolation regions are formed in the semiconductor substrate SUB. Each of the plurality of element isolation regions can be formed by forming a trench in the semiconductor substrate SUB and filling the dielectric film such as a silicon oxide film in the trench. Next, a well region is formed by introducing p-type or n-type impurities into the semiconductor substrate SUB. Next, the transistor 1Q is formed over the semiconductor substrate as a semiconductor element. For example, a gate electrode is formed over the well region through a gate dielectric film, and source and drain regions are formed by introducing p-type or n-type impurities into the well region.

Next, the interlayer dielectric film IL0 is formed over the semiconductor substrate SUB so as to cover the transistor 1Q, for example, by a CVD (Chemical Vapor Deposition) method. Next, a polishing process is performed on the upper surface of the interlayer dielectric film IL0 by a CMP (Chemical Mechanical Polishing) method. Next, the plurality of plugs PG are formed in the interlayer dielectric film IL0.

To form the plurality of plugs PG, first, holes are formed in the interlayer dielectric film IL0 by photolithography technique and anisotropic etching process. Next, a titanium nitride film and a tungsten film are sequentially formed over the interlayer dielectric film IL0 so as to fill the holes, for example, by a CVD method. Next, the titanium nitride film and the tungsten film located outside the holes are removed by a CMP process. In this way, the plurality of plugs PG are formed.

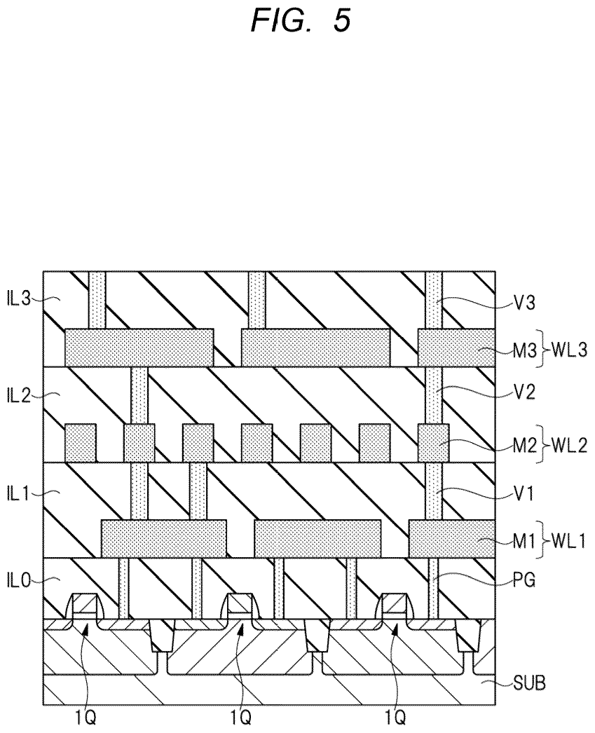

As shown in FIG. 5, the wiring layer WL1, the wiring layer WL2, and the wiring layer WL3 are sequentially formed over the interlayer dielectric film IL0. First, a lower barrier metal film is formed over the interlayer dielectric film IL0. The lower barrier metal film is a laminated film including a titanium film formed by, for example, a sputtering method, and a titanium nitride film formed over the titanium film by, for example, a sputtering method. Next, a conductive film such as an aluminum film or an aluminum alloy film is formed over the lower barrier metal film by, for example, a sputtering method. Then, an upper barrier metal film such as a titanium nitride film is formed over the conductive film by, for example, a sputtering method.

Next, by patterning the upper barrier metal film, the conductive film, and the lower barrier metal film by photolithography technique and anisotropic etching process, the plurality of wirings M1 are formed.

Next, the interlayer dielectric film IL1 is formed over the interlayer dielectric film IL0 by, for example, a CVD method. Then, a polishing process is performed on the upper surface of the interlayer dielectric film IL1 by a CMP method. Next, the plurality of vias V1 are formed in the interlayer dielectric film IL1.

To form the plurality of vias V1, first, holes are formed in the interlayer dielectric film IL1 by photolithography technique and anisotropic etching process. Next, a titanium nitride film and a tungsten film are sequentially formed over the interlayer dielectric film IL1 so as to fill the holes by, for example, a CVD method. Then, by performing a polishing process by a CMP method, the titanium nitride film and the tungsten film located outside the hole are removed. In this way, the plurality of vias V1 are formed.

Thereafter, the wiring M2, the interlayer dielectric film IL2, the via V2, the wiring M3, the interlayer dielectric film IL3, and the via V3 are formed by a method similar to the method of forming the wiring M1, the interlayer dielectric film IL1, and the via V1.

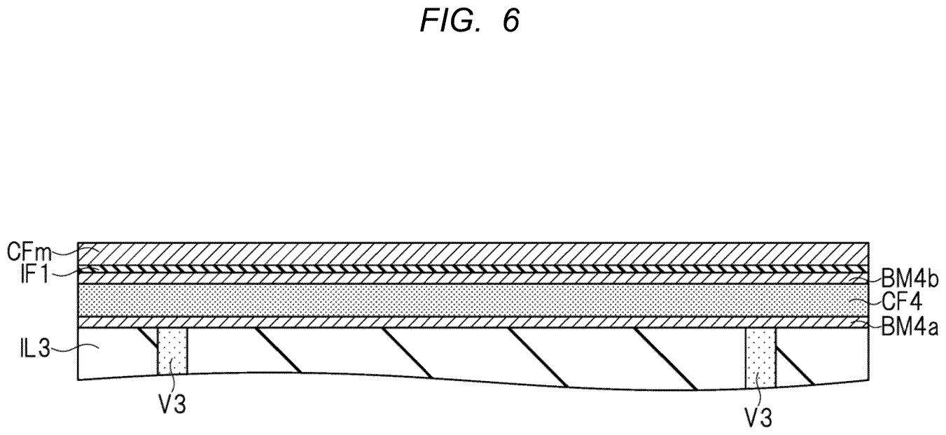

As shown in FIG. 6, first, the lower barrier metal film BM4a is formed over the interlayer dielectric film IL3. The lower barrier metal film BM4a is a laminated film including a titanium film formed by, for example, a sputtering method, and a titanium nitride film formed over the titanium film by, for example, a sputtering method. Next, the conductive film CF4 such as an aluminum film or an aluminum alloy film is formed over the lower barrier metal film BM4a by, for example, a sputtering method. Then, the upper barrier metal film BM4b such as a titanium nitride film is formed over the conductive film CF4 by, for example, a sputtering method. Next, the dielectric film IF1 is formed over the upper barrier metal film BM4b by, for example, a CVD method. Next, a conductive film CFm such as a titanium nitride film is formed over the dielectric film IF1 by, for example, a sputtering method.

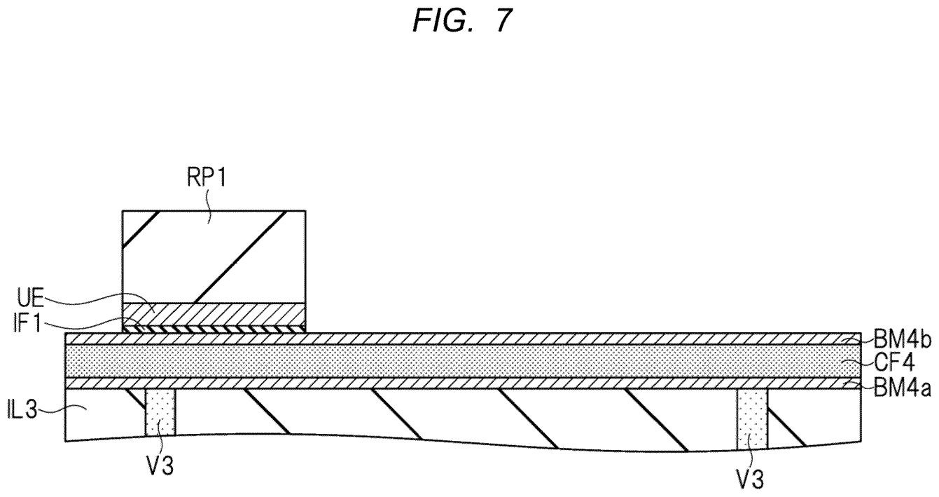

As shown in FIG. 7, by selectively patterning the conductive film CFm and the dielectric film IF1, the conductive film CFm patterned as the upper electrode UE of the capacitor element MIM is formed.

First, a resist pattern RP1 is formed over the conductive film CFm. The resist pattern RP1 has an opening pattern that selectively covers a part of the conductive film CFm. Next, by performing anisotropic etching process using the resist pattern RP1 as a mask, the conductive film CFm and the dielectric film IF1 exposed the resist pattern RP1 are removed. The left conductive film CFm is formed as the upper electrode UE. Thereafter, the resist pattern RP1 is removed by ashing.

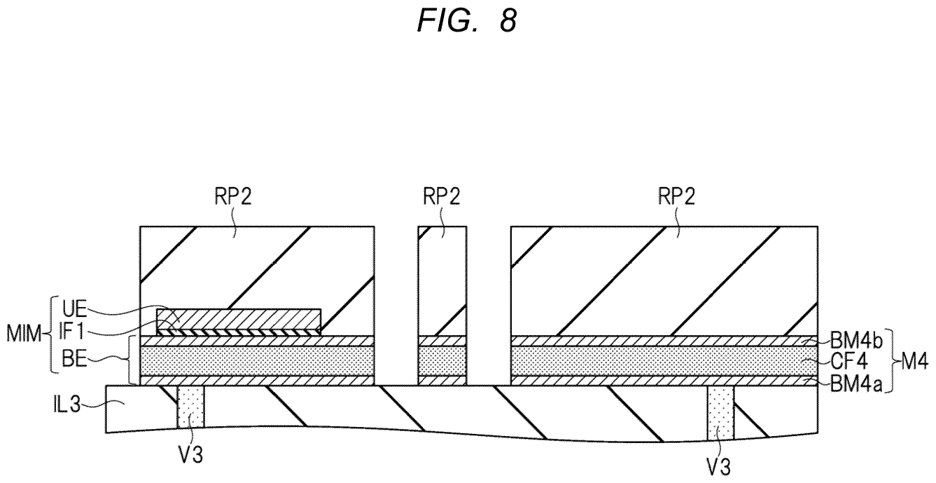

As shown in FIG. 8, by selectively patterning the upper barrier metal film BM4b, the conductive film CF4, and the lower barrier metal film BM4a, the plurality of wirings M4 are formed such that the dielectric film IF1 and the upper electrode UE are left over the upper barrier metal film BM4b. The plurality of wirings M4 include the lower electrode BE of the capacitor element MIM.

First, a resist pattern RP2 is formed over the upper barrier metal film BM4b. The resist pattern RP2 has an opening pattern that selectively covers the region where the dielectric film IF1 and the upper electrode UE are formed over the upper barrier metal film BM4b. Next, by performing anisotropic etching process using the resist pattern RP2 as a mask, the upper barrier metal film BM4b, the conductive film CF4, and the lower barrier metal film BM4a exposed from the resist pattern RP2 are removed. The left upper barrier metal film BM4b, conductive film CF4, and lower barrier metal film BM4a are formed as the plurality of wirings M4. Thereafter, the resist pattern RP2 is removed by ashing.

Although not shown in the figures, patterning may also be performed using a hard mask instead of the resist pattern RP2. First, the dielectric film, for example, a silicon nitride film, is formed over the upper barrier metal film BM4b, for example, by CVD method. Next, the resist pattern RP2 is formed over the dielectric film. Then, by performing anisotropic etching process using the resist pattern RP2 as a mask, the dielectric film exposed from the resist pattern RP2 is removed. The left dielectric film is formed as the hard mask. Thereafter, the resist pattern RP2 is removed by ashing.

The hard mask has the same opening pattern as the resist pattern RP2. By performing anisotropic etching process using the hard mask, the upper barrier metal film BM4b, the conductive film CF4, and the lower barrier metal film BM4a exposed from the hard mask are removed. The left upper barrier metal film BM4b, conductive film CF4, and lower barrier metal film BM4a are formed as the plurality of wirings M4.

Patterning using the resist pattern, or a hard mask processed using the resist pattern, is not limited to the formation of the wiring M4 but may also be performed for the formation of the wiring M1, the wiring M2, the wiring M3, the wiring M5, or the wiring M6.

Thus, through the manufacturing steps shown in FIGS. 6 to 8, the plurality of wirings M4 and the dielectric film IF1 and the upper electrode UE, which are sequentially laminated over the lower electrode BE, are formed over the interlayer dielectric film IL3.

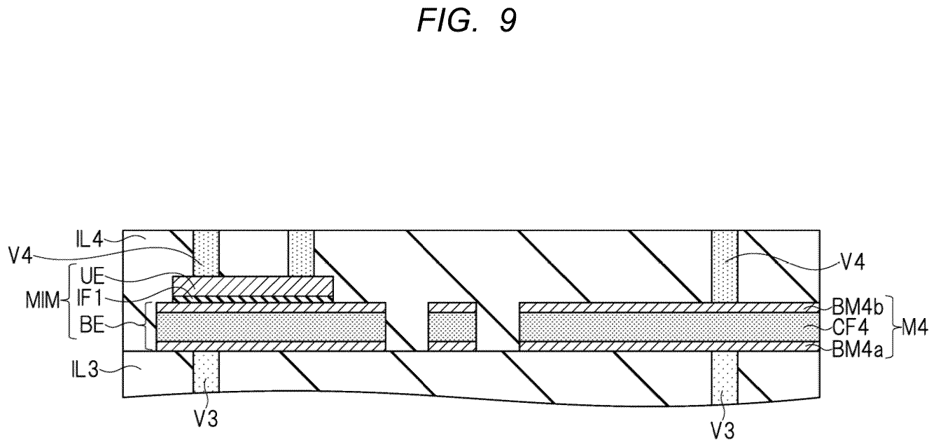

As shown in FIG. 9, the interlayer dielectric film IL4 is formed over the interlayer dielectric film IL3 so as to cover the plurality of wirings M4 including the lower electrode BE, the dielectric film IF1, and the upper electrode UE, for example, by a CVD method. Next, a polishing process is performed on the upper surface of the interlayer dielectric film IL4 by a CMP method. Next, the plurality of vias V4 are formed in the interlayer dielectric film IL4. The method of forming the vias V4 is similar to the method of forming the vias V1.

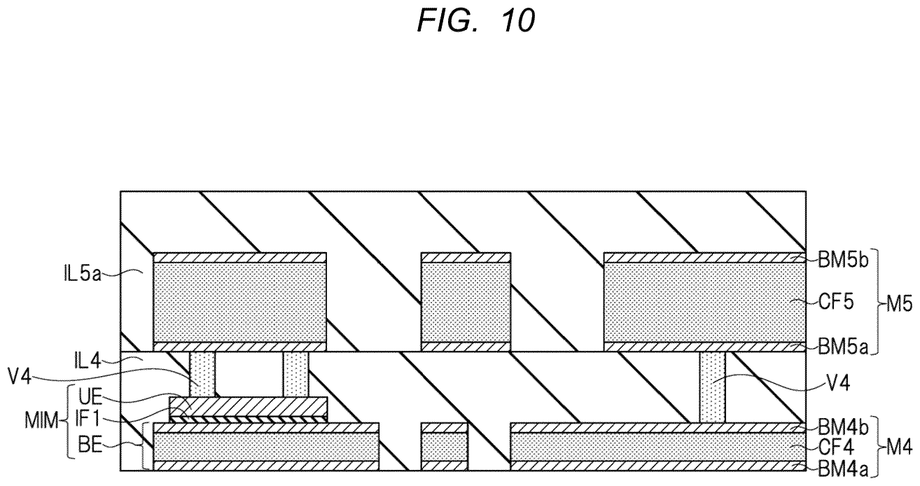

As shown in FIG. 10, first, the plurality of wirings M5 are formed over the interlayer dielectric film IL4. The method of forming the wirings M5 is similar to the method of forming the wirings M4. However, the thicknesses of the upper barrier metal film BM5b, the conductive film CF5, and the lower barrier metal film BM5a are different from the thicknesses of the upper barrier metal film BM4b, the conductive film CF4, and the lower barrier metal film BM4a, respectively.

Next, the interlayer dielectric film IL5a is formed over the interlayer dielectric film IL4 so as to cover the plurality of wirings M5, for example, by a CVD method. Next, a polishing process is performed on the upper surface of the interlayer dielectric film IL5a by a CMP method.

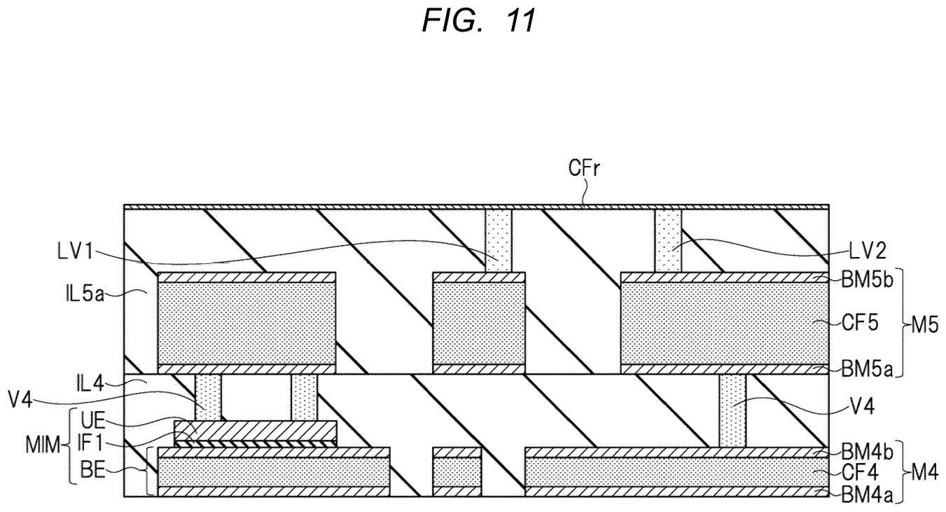

As shown in FIG. 11, first, the local via LV1 and the local via LV2 are formed in the interlayer dielectric film IL5a. The method of forming the local via LV1 and the local via LV2 is similar to the method of forming the vias V1. The local via LV1 and the local via LV2 are formed so as to be connected to different wirings M5, respectively. Next, a conductive film CFr is formed over the interlayer dielectric film IL5a, for example, by a sputtering method.

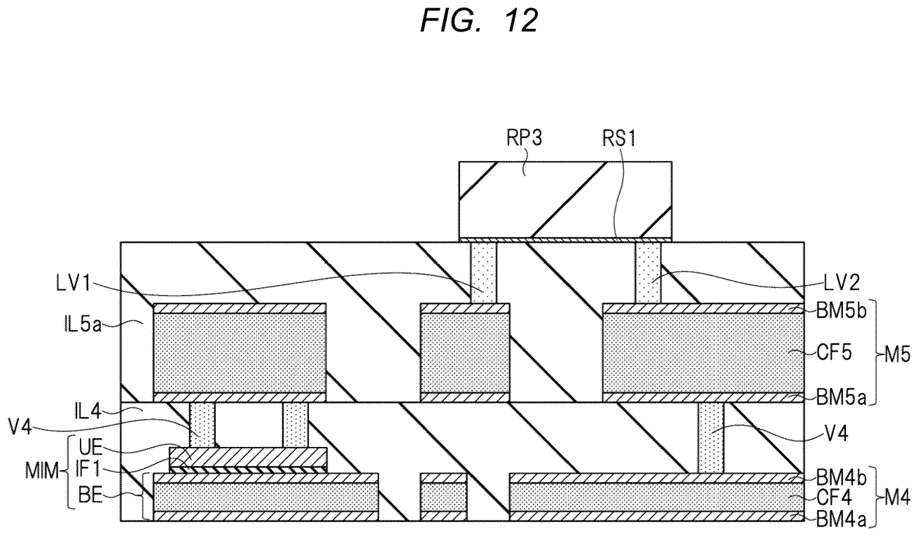

As shown in FIG. 12, by selectively patterning the conductive film CFr, the resistor element RS1 connected to the local via LV1 and the local via LV2 is formed.

First, a resist pattern RP3 is formed over the conductive film CFr. The resist pattern RP3 has an opening pattern that selectively covers a part of the conductive film CFr. Next, by using the resist pattern RP3 as a mask, an anisotropic etching process is performed to remove the exposed conductive film CFr. The left conductive film CFr is formed as the resistor element RS1. Subsequently, the resist pattern RP3 is removed by ashing.

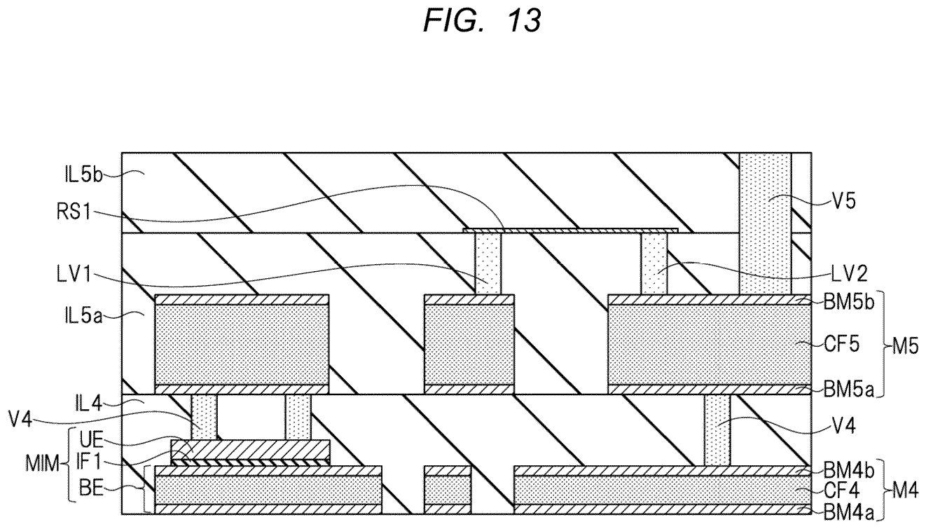

As shown in FIG. 13, first, the interlayer dielectric film IL5b is formed over the interlayer dielectric film IL5a so as to cover the resistor element RS1, for example, by a CVD method. Next, a polishing process is performed on the upper surface of the interlayer dielectric film IL5b by a CMP method.

Next, the plurality of vias V5 are formed in the interlayer dielectric film IL5b and the interlayer dielectric film IL5a. The method of forming the vias V5 is similar to the method of forming the vias V1. However, the diameter, the thickness of the titanium nitride film, and the thickness of the tungsten film in the vias V5 are different from the diameter, the thickness of the titanium nitride film, and the thickness of the tungsten film in the vias V1.

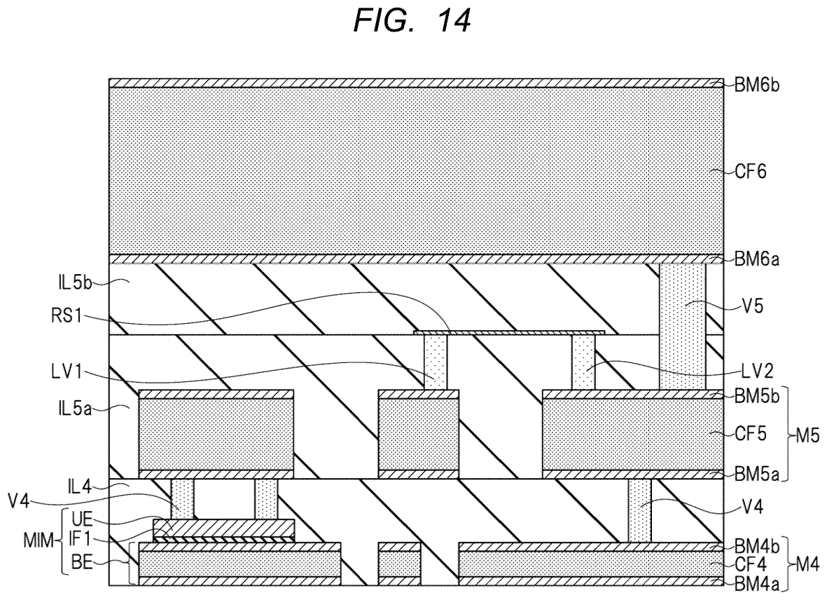

As shown in FIG. 14, first, the lower barrier metal film BM6a is formed over the interlayer dielectric film IL5b. The lower barrier metal film BM6a is a laminated film including a titanium film formed over the interlayer dielectric film IL5b, for example, by sputtering, and a titanium nitride film formed over the titanium film, for example, by sputtering. Next, the conductive film CF6 such as an aluminum film or an aluminum alloy film is formed over the lower barrier metal film BM6a, for example, by sputtering method. Then, the upper barrier metal film BM6b such as a titanium nitride film is formed over the conductive film CF6, for example, by sputtering method.

Thereafter, by selectively patterning the upper barrier metal film BM6b, the conductive film CF6, and the lower barrier metal film BM6a, the plurality of wirings M6 are formed. Thus, the structures shown in FIGS. 1 and 2 are obtained.

To pattern the plurality of wirings M6, first, a resist pattern is formed over the upper barrier metal film BM6b. The resist pattern has an opening pattern that selectively covers a part of the upper barrier metal film BM6b. Next, by performing anisotropic etching process using the resist pattern as a mask, the exposed upper barrier metal film BM6b, conductive film CF6, and lower barrier metal film BM6a are removed. The left upper barrier metal film BM6b, conductive film CF6, and lower barrier metal film BM6a are formed as the plurality of wirings M6. Thereafter, the resist pattern is removed by ashing.

### Main Features of the Semiconductor Device

### Formation Position of the Resistor Element Rs1

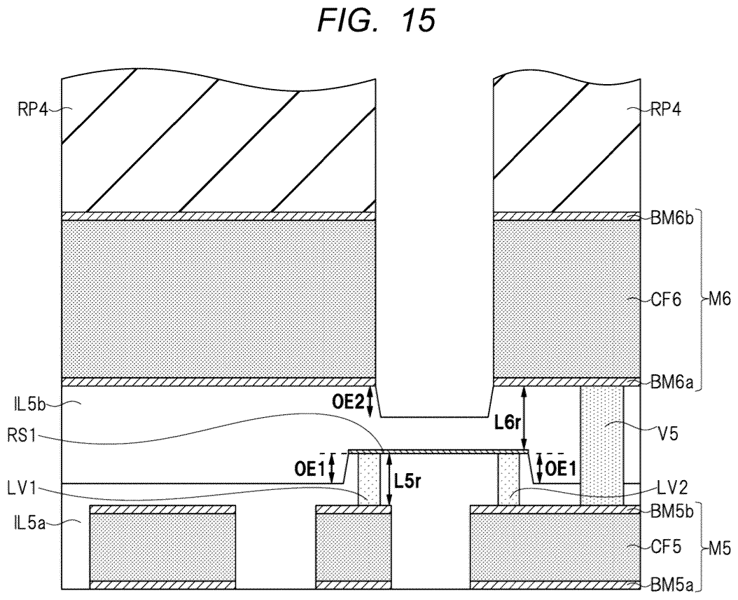

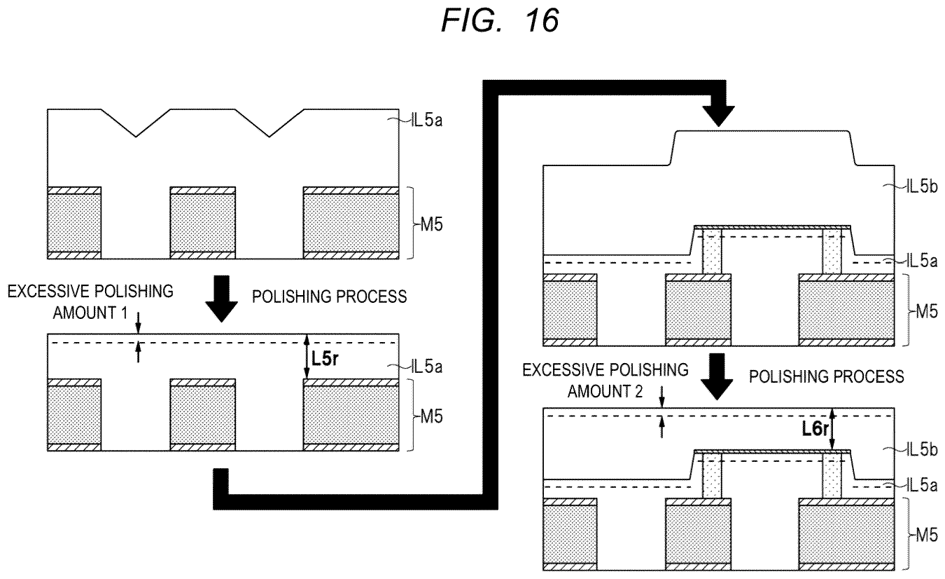

Theoretically, the resistor element RS1 can be formed between wiring layers, but in the first embodiment, the resistor element RS1 is formed between the wiring layer WL6 and the wiring layer WL5. The reason for this is explained below using FIGS. 15 and 16. To form the resistor element RS1 between wiring layers, the following first condition, second condition, and third condition must be satisfied.

As shown in FIG. 15, the first condition is that the over-etching amount OE1 of the anisotropic etching process performed when forming the resistor element RS1 is less than the distance L5r. That is, the over-etching during patterning of the conductive film CFr does not reach the wiring M5.

Referring back to FIG. 12, the resistor element RS1 is formed by performing anisotropic etching process on the conductive film CFr using the resist pattern RP3 as a mask. At this time, since the uniformity of etching varies in the same semiconductor substrate SUB, over-etching is performed so that unnecessary conductive film CFr is not left. Therefore, a part of the interlayer dielectric film IL5a exposed from the resistor element RS1 is also etched. The over-etching amount OE1 is, for example, 100 nm or more and 120 nm or less.

The second condition is that the over-etching amount OE2 of the anisotropic etching process performed when forming the wiring M6 is less than the distance L6r. That is, the over-etching during patterning of the wiring M6 does not reach the conductive film CFr.

For example, the wiring M6 is formed by performing an anisotropic etching process using a resist pattern RP4 as a mask. Here, over-etching is performed so that unnecessary lower barrier metal film BM6a and the like are not left behind. Therefore, a part of the interlayer dielectric film IL5b exposed from the wiring M6 is also etched. The amount of over-etching OE2 is, for example, 60 nm or more and 80 nm or less.

As shown in FIG. 16, the third condition is that the variation in the amount of polishing by the CMP method is considered. After the formation of the interlayer dielectric film, polishing is performed on the upper surface of the interlayer dielectric film, but the uniformity of the amount of polishing differs in the same semiconductor substrate SUB. Therefore, it is necessary to consider the amount of excessive polishing when polished more than the set value.

In order to form the resistor element RS1 between wiring layers, it is necessary to divide the formation of the interlayer dielectric film into two, such as interlayer dielectric film IL5a and interlayer dielectric film IL5b. Therefore, since the polishing process by the CMP method is performed twice, it is necessary to calculate the amount of excessive polishing for two times.

When performing the polishing process on the upper surface of each of the interlayer dielectric film IL5a and the interlayer dielectric film IL5b, the excessive polishing amount 1 and the excessive polishing amount 2 are calculated. For example, if the distance L5r is set to 230 nm, 15% of the distance L5r is calculated as the excessive polishing amount 1 (34.5 nm). Also, if the distance L6r is set to 250 nm, 15% of the distance L6r is calculated as the excessive polishing amount 2 (37.5 nm).

Thus, considering the first condition, the second condition, and the third condition, it is necessary to consider approximately 250 nm as the minimum manufacturing margin between the resistor element RS1 and the wiring layer WL6 and between the resistor element RS1 and the wiring layer WL5, respectively.

As a comparative example, the case where the resistor element RS1 is formed between the wiring layer WL4 and the wiring layer WL5 is considered. As the semiconductor device is miniaturized, the value of distance L45 becomes smaller. Therefore, there may be cases where it is not possible to form the resistor element RS1 between the wiring layer WL4 and the wiring layer WL5. Moreover, even if it is possible to form the resistor element RS1, the distance between the resistor element RS1 and the wiring layer WL4, and the distance between the resistor element RS1 and the wiring layer WL5 are short. Therefore, in the event of unexpected defects other than those related to the first condition, the second condition, and the third condition, it is difficult to make design changes or take measures. That is, in the comparative example, it is difficult to stably manufacture the resistor element RS1.

As described above, in the first embodiment, the resistor element RS1 is formed between the wiring layer WL5 and the wiring layer WL6, which is the longest distance L56 among the layers. Since the resistor element RS1 can be formed with a sufficient manufacturing margin, it is possible to maintain the characteristics of the resistor element RS1 and secure the reliability of the semiconductor device.

### Formation Position of Capacitance Element Mim

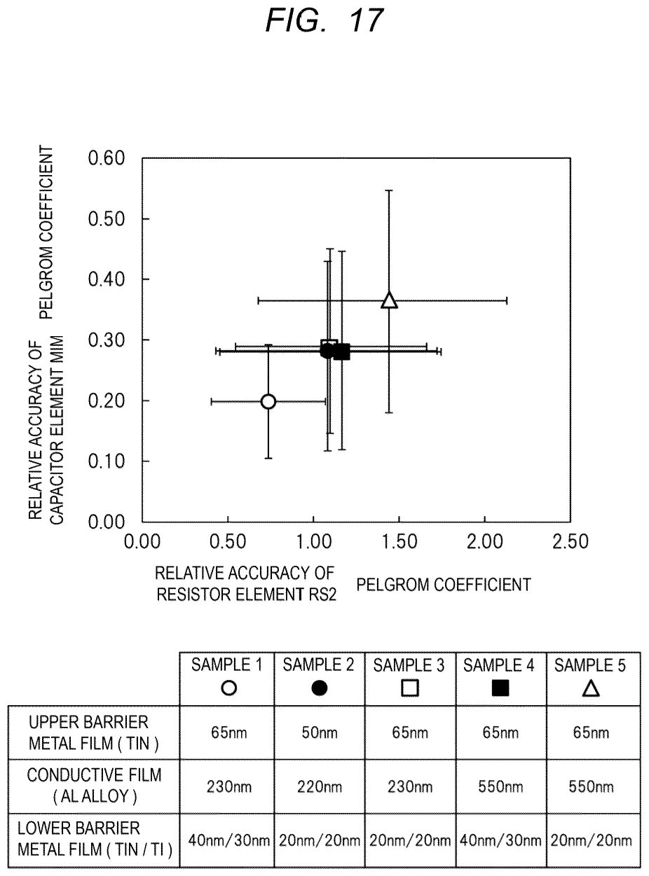

FIG. 17 is data that the inventors of the present application have studied about the relative accuracy of a plurality of capacitor elements MIM formed over the same semiconductor substrate SUB. The vertical axis of the graph in FIG. 17 indicates the Pelgrom coefficient of the capacitor element MIM. The smaller the value of the Pelgrom coefficient, the better the relative accuracy, and the smaller the variation in characteristics among the plurality of capacitor elements MIM. The error range was calculated as 30 of the variation occurring in the plurality of semiconductor substrates SUB.

The upper surface of the upper barrier metal film is not a perfect flat surface, but has irregularities formed over it. The occurrence of these irregularities is due not only to the accuracy of the film formation process of the upper barrier metal film but also to the irregular surface shape of the underlying film. Therefore, the fewer the irregularities in the underlying film, the less likely it is for irregularities to occur in the film that becomes the upper layer. Furthermore, the fewer the irregularities in the upper barrier metal film, the fewer the irregularities that occur in the dielectric film IF1 and the upper electrode UE formed over the upper barrier metal film. Therefore, the relative accuracy of the capacitor element MIM can be improved.

Comparing Sample 5 and Sample 4, the thickness of the upper barrier metal film is the same for both, and the thickness of the conductive film is the same for both, but the thickness of the lower barrier metal film of Sample 4 is greater than that of Sample 5. Therefore, the greater the thickness of the lower barrier metal film, the fewer the irregularities that occur in the conductive film and the upper barrier metal film that become the upper layer, and the relative accuracy of the capacitor element MIM is improved.

Furthermore, comparing Sample 5 and Sample 3, the thickness of the upper barrier metal film is the same for both, and the thickness of the lower barrier metal film is the same for both, but the thickness of the conductive film of Sample 3 is smaller than that of Sample 5. Therefore, the smaller the thickness of the conductive film, the fewer the irregularities that occur in the upper barrier metal film, and the relative accuracy is improved. The results of Sample 2 were almost the same as those of Sample 3.

Therefore, as can be seen by comparing Sample 5 and Sample 1, the smaller the thickness of the conductive film and the greater the thickness of the lower barrier metal film, the more effectively the relative accuracy of the capacitor element MIM can be improved. For example, by setting the thickness of the conductive film CF4 to 230 nm or less and the thickness of the lower barrier metal film BM4a to 40 nm or more, the relative accuracy of the capacitor element MIM can be more effectively improved.

The thickness of each wiring is primarily the thickness of the conductive film such as an aluminum film or an aluminum alloy film. Therefore, in the first embodiment, the conductive film CF4 having a thickness smaller than that of conductive film CF5 and conductive film CF6 is applied. That is, among the wirings formed in the multilayer wiring layer, the wiring M4 having the smallest thickness is used as the lower electrode BE of the capacitor element MIM. This allows for the improvement of the relative accuracy of the capacitor element MIM, thereby improving the performance of the semiconductor device.

### Other Features Regarding the Formation Positions of Resistor Element Rs1 and Capacitor Element Mim

The resistor element RS1 and the capacitor element MIM are arranged so as not to overlap each other in plan view. In other words, the resistor element RS1 is arranged not to be formed directly over the capacitor element MIM.

During the formation of the interlayer dielectric film IL4, the upper surface of the interlayer dielectric film IL4 is planarized by polishing process using the CMP method. However, directly over the capacitor element MIM, due to the thickness of the dielectric film IF1 and the thickness of the upper electrode UE, the upper surface of the interlayer dielectric film IL4 is raised compared to directly over the other wiring M4. Therefore, even after polishing process, the upper surface of the interlayer dielectric film IL4 located directly over the capacitor element MIM may not be completely planarized.

In that case, directly over the capacitor element MIM, the raised shape of the upper surface of the interlayer dielectric film IL4 may be reflected in the interlayer dielectric film IL5a, and the upper surface of the interlayer dielectric film IL5a may also have a raised shape. If the resistor element RS1 is formed over the upper surface of the interlayer dielectric film IL5a including such a raised shape, it becomes difficult to form the resistor element RS1 with a uniform thickness. This may cause variations in the characteristics of the resistor element RS1. If the resistor element RS1 and the capacitor element MIM are formed so as not to overlap each other in plan view, such a risk can be eliminated.

It is preferable that the resistor element RS1 and the capacitor element MIM are formed between different wiring layers. For example, the case of forming both the resistor element RS1 and the capacitor element MIM in the wiring layer WL5 is considered. If the resistor element RS1 is formed first, since the wiring M4, which functions as the lower electrode BE of the capacitor element MIM, is covered by the interlayer dielectric film IL5a, an additional process such as partially opening a part of the wiring M4 is required, complicating the manufacturing step.

On the other hand, if the capacitor element MIM is formed first, it is necessary to completely cover the upper electrode UE of the capacitor element MIM with the interlayer dielectric film IL5a. This is because if the upper electrode UE is exposed from the interlayer dielectric film IL5a, it may be scraped off during the patterning of the resistor element RS1. Then, it is necessary to lengthen the distance L5r, but as the distance L5r is lengthened, the distance L6r becomes shorter, which may expose the resistor element RS1 to over-etching. To eliminate such a risk, lengthening the distance L6r results in a longer distance L56 between the wiring layer WL6 and the wiring layer WL5, making it difficult to miniaturize the semiconductor device. Also, during the formation of the via V5, the depth of the hole becomes larger, and the aspect ratio becomes higher, making it difficult to properly fill the hole with a tungsten film or the like.

### Second Embodiment

The following description will mainly explain the differences from the first embodiment and omit the description of points overlapping with the first embodiment.

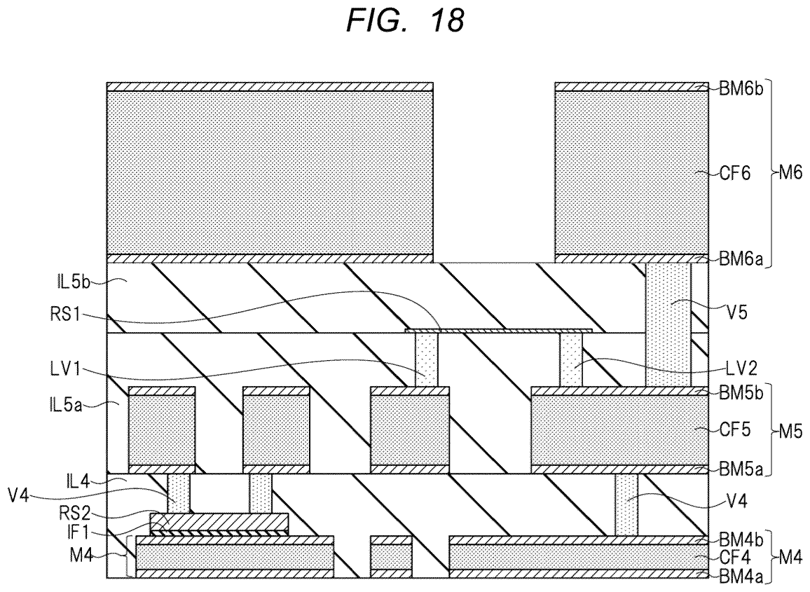

As shown in FIG. 18, in the second embodiment, the conductive film CFm, which functions as the upper electrode UE in the first embodiment, is made to function as a resistor element RS2 electrically connected to the different wiring M5. The resistor element RS2 is connected to one via V4, and one via V4 is connected to one wiring M5. Also, the resistor element RS2 is connected to another via V4, and another via V4 is connected to another wiring M5.

As shown in FIG. 17, similar to the capacitor element MIM, with the resistor element RS2, the smaller the thickness of the conductive film and the greater the thickness of the lower barrier metal film, the higher the relative accuracy that can be achieved. Therefore, in the second embodiment, among the wirings formed in the multilayer wiring layer, the dielectric film IF1 and the resistor element RS2 are formed over the wiring M4 having the smallest thickness. Accordingly, it is possible to improve the relative accuracy of the resistor element RS2, and to enhance the performance of the semiconductor device.

The resistor element RS2, similar to the upper electrode UE, is formed between the wiring layer WL5 and the wiring layer WL4, but the wiring M4 over which the resistor element RS2 is formed differs from the wiring M4 over which the upper electrode UE is formed. In other words, the resistor element RS2 is positioned so as not to overlap with the capacitor element MIM in plan view. Furthermore, the resistor element RS2 and the upper electrode UE can be formed in the same manufacturing step. Therefore, it is possible to suppress an increase in manufacturing costs. It should be noted that although the thickness of each of the resistor element RS2 and the upper electrode UE is the same, their respective lengths, planar shapes, and planar areas differ from each other.

In the first embodiment, the resistor element RS1 and the capacitor element MIM are formed so as not to overlap with each other in plan view, and for the same reason, the resistor element RS1 and the resistor element RS2 are formed so as not to overlap with each other in plan view.

### Third Embodiment

The following description primarily explains the differences from the first embodiment and omits the description of aspects that overlap with the first embodiment.

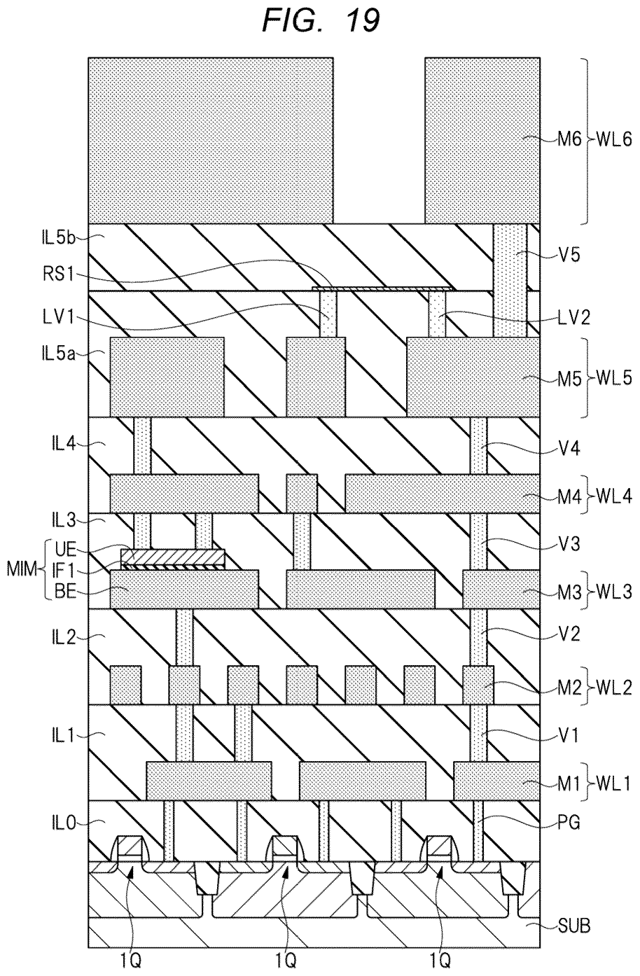

In the first embodiment, the wiring M4 is used as the lower electrode BE, and the upper electrode UE and the dielectric film IF1 are formed between the wiring layer WL5 and the wiring layer WL4. As shown in FIG. 19, in the third embodiment, the wiring M3 is used as the lower electrode BE, and the upper electrode UE and the dielectric film IF1 are formed between the wiring layer WL4 and the wiring layer WL3.

In other words, the distance between the resistor element RS1 and the capacitor element MIM in the third embodiment is longer than the distance between the resistor element RS1 and the capacitor element MIM in the first embodiment.

Heat generated by the resistor element RS1 may vary the characteristics of the capacitor element MIM. Similarly, heat generated by the capacitor element MIM may vary the characteristics of the resistor element RS1. By increasing the distance between the resistor element RS1 and the capacitor element MIM, it is possible to suppress these changes in characteristics.

It is also possible to use the wiring M2 as the lower electrode BE and form the upper electrode UE and the dielectric film IF1 between the wiring layer WL3 and the wiring layer WL2. Furthermore, it is possible to use the wiring M1 as the lower electrode BE and form the upper electrode UE and the dielectric film IF1 between the wiring layer WL2 and the wiring layer WL1. That is, it is sufficient if there is one or more other wiring layers between the wiring layer in which the wiring connected electrically to the resistor element RS1 is formed and the wiring layer in which the lower electrode BE of the capacitor element MIM is formed.

Similarly, the concept applicable to the resistor element RS2 of the second embodiment can also be applied to the capacitor element MIM of the third embodiment. That is, the resistor element RS2 may be formed between the wiring layer WL4 and the wiring layer WL3, between the wiring layer WL3 and the wiring layer WL2, or between the wiring layer WL2 and the wiring layer WL1.

Although the present invention has been specifically described based on the embodiments, it is not limited to these embodiments and can be modified in various ways without departing from the spirit of the invention.

What is claimed is:

1. A semiconductor device comprising:
a semiconductor substrate;
a multilayer wiring layer formed over the semiconductor substrate, the multilayer wiring layer comprising a first wiring layer and a second wiring layer located over the first wiring layer;
a first wiring formed in the first wiring layer;
a second wiring formed in the second wiring layer, the second wiring having a thickness greater than a thickness of the first wiring;
a third wiring formed in the second wiring layer, the third wiring having a thickness greater than the thickness of the first wiring;
a first dielectric film formed between the first wiring layer and the second wiring layer, the first dielectric film being formed over the first wiring;
a first conductive film formed between the first wiring layer and the second wiring layer, the first conductive film being formed over the first dielectric film; and
a second conductive film formed over the second wiring and over the third wiring;
wherein the first wiring, the first dielectric film and the first conductive film function as a capacitor element, and
wherein the second conductive film functions as a first resistor element electrically connected to the second wiring and the third wiring.

2. The semiconductor device according to claim 1, comprising:
a first interlayer dielectric film covering the second wiring and the third wiring;
a first via formed in the first interlayer dielectric film so as to be connected to the second wiring; and
a second via formed in the first interlayer dielectric film so as to be connected to the third wiring,
wherein the second conductive film is formed over the first interlayer dielectric film so as to be connected to the first via and the second via.

3. The semiconductor device according to claim 2,
wherein the multilayer wiring layer comprises a third wiring layer located over the second wiring layer,
wherein the semiconductor device comprises:
a second interlayer dielectric film formed over the first interlayer dielectric film so as to cover the second conductive film; and
a fourth wiring formed in the third wiring layer and formed over the second interlayer dielectric film, the fourth wiring having a thickness greater than the thickness of the second wiring,
wherein in a direction orthogonal to an upper surface of the semiconductor substrate, a distance between the third wiring layer and the second wiring layer is longer than a distance between the second wiring layer and the first wiring layer.

4. The semiconductor device according to claim 3,
wherein the distance between the third wiring layer and the second wiring layer is 500 nm or more.

5. The semiconductor device according to claim 4,
wherein the second conductive film comprises at least one of SiCr film, SiCrC film, NiCr film, TiN film and TaN film.

6. The semiconductor device according to claim 1,
wherein the first wiring comprises:
a first barrier metal film;
a third conductive film formed over the first barrier metal film; and
a second barrier metal film formed over the third conductive film,
wherein a thickness of the first barrier metal film is 40 nm or more,
wherein a thickness of the third conductive film is 230 nm or less, and
wherein a thickness of the second barrier metal film is 50 nm or more.

7. The semiconductor device according to claim 6,
wherein the first barrier metal film comprises TiN film and Ti film,
wherein the third conductive film comprises Al film or Al alloy film,
wherein the second barrier metal film comprises TiN film, and
wherein the first conductive film comprises TiN film.

8. The semiconductor device according to claim 6, comprising:
a fifth wiring and a sixth wiring each formed in the second wiring layer and each having a thickness greater than the thickness of the first wiring; and
a fourth conductive film formed between the first wiring layer and the second wiring layer,
wherein the fourth conductive film functions as a second resistor element electrically connected to the fifth wiring and the sixth wiring.

9. The semiconductor device according to claim 1,
wherein the first resistor element and the capacitor element are disposed so as not to overlap each other in plan view.

10. The semiconductor device according to claim 1,
wherein at least one wiring layer is disposed between the first wiring layer and the second wiring layer.

11. A method of manufacturing a semiconductor device, the method comprising:
(a) preparing a semiconductor substrate;
(b) after the (a), forming a first interlayer dielectric film over the semiconductor substrate;
(c) after the (b), forming a first wiring over the first interlayer dielectric film and forming a first dielectric film and a first conductive film sequentially laminated over the first wiring;
(d) after the (c), forming a second interlayer dielectric film over the first interlayer dielectric film so as to cover the first wiring, the first dielectric film and the first conductive film;
(e) after the (d), forming a second wiring and a third wiring over the second interlayer dielectric film;
(f) after the (e), forming a third interlayer dielectric film over the second interlayer dielectric film so as to cover the second wiring and the third wiring;
(g) after the (f), forming a first via in the third interlayer dielectric film so as to be connected to the second wiring and forming a second via in the third interlayer dielectric film so as to be connected to the third wiring; and
(h) after the (g), forming a second conductive film over the third interlayer dielectric film so as to be connected to the first via and the second via,
wherein a thickness of the first wiring is smaller than a thickness of the second wiring and a thickness of the third wiring,
wherein the first wiring, the first dielectric film and the first conductive film function as a capacitor element, and
wherein the second conductive film functions as a resistor element electrically connected to the second wiring and the third wiring.

12. The method according to claim 11, comprising:
(i) after the (h), forming a fourth interlayer dielectric film over the third interlayer dielectric film so as to cover the second conductive film; and
(j) after the (i), forming a fourth wiring over the fourth interlayer dielectric film,
wherein a sum of a thickness of a part of the third interlayer dielectric film located over the second wiring or over the third wiring and a thickness of a part of the fourth interlayer dielectric film located over the second wiring or over the third wiring is greater than a thickness of a part of the second interlayer dielectric film located over the first wiring.

13. The method according to claim 12, comprising:
(k) between the (b) and the (c), performing a first polishing process on an upper surface of the first interlayer dielectric film by CMP method;
(l) between the (d) and the (e), performing a second polishing process on an upper surface of the second interlayer dielectric film by CMP method;
(m) between the (f) and the (g), performing a third polishing process on an upper surface of the third interlayer dielectric film by CMP method; and
(n) between the (i) and the (j), performing a fourth polishing process on an upper surface of the fourth interlayer dielectric film by CMP method.

14. The method according to claim 13,
wherein the sum of the thickness of the part of the third interlayer dielectric film located over the second wiring or over the third wiring and the thickness of the part of the fourth interlayer dielectric film located over the second wiring or over the third wiring is 500 nm or more.

15. The method according to claim 13,
wherein the (j) comprises:
(j1) forming a first barrier metal film, a third conductive film and a second barrier metal film over the fourth interlayer dielectric film; and
(j2) after the (j1), selectively patterning the first barrier metal film, the third conductive film and the second barrier metal film to form the fourth wiring,
wherein in the (j2), a part of the fourth interlayer dielectric film exposed from the fourth wiring is etched using anisotropic etching process.

16. The method according to claim 13,
wherein the (h) comprises:
(h1) forming a second conductive film over the third interlayer dielectric film; and
(h2) after the (h1), selectively patterning the second conductive film to form the first resistor element connected to the first via and the second via,
wherein in the (h2), a part of the third interlayer dielectric film exposed from the first resistor element using anisotropic etching process.

17. The method according to claim 11,
wherein the (c) comprises:
(c1) sequentially forming a third barrier metal film, a fourth conductive film, a fourth barrier metal film, the first dielectric film and the first conductive film over the first interlayer dielectric film;
(c2) after the (c1), selectively patterning the first dielectric film and the first conductive film; and
(c3) after the (c2), selectively patterning the third barrier metal film, the fourth conductive film and the fourth barrier metal film to form the first wiring such that the first dielectric film and the first conductive film are left over the fourth barrier metal film,
wherein a thickness of the third barrier metal film is 40 nm or more,
wherein a thickness of the fourth conductive film is 230 nm or less, and
wherein a thickness of the fourth barrier metal film is 50 nm or more.

18. The method according to claim 11, comprising:
(o) between the (d) and the (e), forming a third via and a fourth via in the second interlayer dielectric film,
wherein in the (c), a fifth wiring is formed over the first interlayer dielectric film and a second dielectric film and a fifth conductive film are sequentially formed over the fifth wiring,
wherein in the (d), the second interlayer dielectric film is formed so as to cover the fifth wiring, the second dielectric film and the fifth conductive film,
wherein in the (e), a sixth wiring connected to the third via and a seventh wiring connected to the fourth via are formed over the second interlayer dielectric film,
wherein the third via and the fourth via are formed so as to be connected to the fifth conductive film, and
wherein the fifth conductive film functions as a second resistor element electrically connected to the sixth wiring and the seventh wiring.

19. The method according to claim 11,
wherein the first resistor element and the capacitor element are disposed so as not to overlap each other in plan view.

20. The method according to claim 11, comprising:
(p) between the (d) and the (e), forming an eighth wiring over the second interlayer dielectric film; and
(q) between the (p) and the (e), forming a fifth interlayer dielectric film over the second interlayer dielectric film so as to cover the eighth wiring,
wherein in the (e), the second wiring and the third wiring are formed over the fifth interlayer dielectric film,
wherein in the (f), the third interlayer dielectric film is formed over the fifth interlayer dielectric film, and
wherein a thickness of the eighth wiring is smaller than the thickness of the second wiring and the thickness of the third wiring.
